(19) United States
(12) Patent Application Publication
(10) Pub. No.: US 2008/0049823 A1
(43) Pub. Date: Feb. 28, 2008

(54) Methods and apparatuses for processing complex signals

(75) Inventors: Ki-Dong Kang, Gwacheon-si (KR); Tae-Sung Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/476,036

(22) Filed: Jun. 28, 2006

(51) Int. Cl. H03K 5/159; H04B 1/10

(52) U.S. Cl. 375/232; 375/350

(57) ABSTRACT

A method for processing at least one complex signal may include equalizing compensating for a phase error of an input complex signal. The input complex signal may include a first channel signal and a second channel signal, which is perpendicular to the first channel signal. A phase imbalance and an amplitude imbalance between a first channel signal and a second channel signal may be compensated to generate an imbalance compensated signal.

### BACKGROUND OF THE INVENTION

1. Field of the Invention

Example embodiments of the present invention relate to methods and apparatuses for processing complex signals, for example, methods and an apparatuses for processing complex signals to compensate for phase and/or amplitude imbalances.

2. Description of the Related Art

Quadrature amplitude modulation (QAM) is a widely used method of modulating wireless communication signals (e.g., high-speed wireless communication signals).

A QAM signal includes an in-phase channel signal (hereinafter an I-signal) and a quadrature channel signal (hereinafter a Q-signal) perpendicular to the I-signal. The I-signal and the Q-signal may be independently modulated by an amplitude-shift keying (ASK) method, and transmitted through two carrier waves (e.g., a sine wave and a cosine wave) that are perpendicular to one another. The QAM signal is a complex signal including the two perpendicular signals, and may have double the data transfer rate as compared to the ASK signal.

FIG. 1 is a diagram illustrating a 64-QAM signal constellation. A 64-QAM signal includes an I-signal and a Q-signal, each of which has eight levels. The 64-QAM signal may represent 64 different values, and may transfer 6-bit data.

Referring to FIG. 1, the horizontal axis indicates a value of the I-signal and the vertical axis indicates a value of the O-signal. One constellation point is determined by the I-signal and the Q-signal, and the determined constellation point may be mapped to 6-bit data.

The QAM signal may be degraded by fading effects, such as, multiple paths, imperfect isolation of a receiver and/or mismatch of elements included in the receiver. As a result, a QAM demodulator may not obtain data by a direct mapping of the received QAM signal. A conventional QAM demodulator may equalize a received QAM signal using an equalizer, and may map the equalized signal to receive the transmitted data.

An equalizer may have various configurations depending on the system. For example, some conventional equalizing devices may include a phase-tracking loop, an equalizer and a complex multiplier, as shown, for example, in FIGS. 2 and 3.

FIG. 2 is a block diagram illustrating a conventional equalizing device including a phase-tracking loop, an equalizer and a complex multiplier. As shown, the equalizing device 200 may include an equalizer 201, a phase-tracking loop 202 and a complex multiplier 203. The equalizer 201 and the phase-tracking loop 202 may cooperate or work in conjunction with each other. In example operation, the phase-tracking loop 202 may calculate a phase compensation value based on an output signal, and provide the phase compensation value to the complex multiplier 203.

The complex multiplier 203 may compensate for the phase error by multiplying an input signal by the calculated phase compensation value. The equalizer 201 for equalizing the input signal may include a feedforward filter 210, an adder 220, a feedback filter 230, a decision unit 240 and an error calculation unit 250. The decision unit 240 may decide which data is mapped to the equalized signal.

The feedforward filter 210 may multiply an output signal from the complex multiplier 203 by a coefficient provided by the error calculation unit 250. The feedback filter 230 multiplies the data from the decision unit 240 by the coefficient provided by the error calculation unit 250. The adder 220 may generate the output signal by adding an output of the feedforward filter 210 and an output of the feedback filter 230.

The equalizing device 200 may compensate for the phase error of the input signal, and equalize the phase compensated signal. Alternatively, the phase error compensation may be performed after the input signal is equalized, or equalization and compensation may be performed simultaneously.

FIG. 3 is a block diagram illustrating another conventional equalizing device including a phase-tracking loop, an equalizer and a complex multiplier.

As shown, the equalizing device 300 may include an equalizer 301, a phase-tracking loop 302, and a complex multiplier 303. The equalizer 301 and the phase-tracking loop 302 may cooperate with each other.

The equalizer 301 may equalize an input signal and the complex multiplier 303 may compensate for the phase error of the equalized signal. The phase compensated signal is provided to the phase-tracking loop 302 so that the phase-tracking loop 302 may calculate a phase compensation value. The phase compensated value is provided to the complex multiplier 303 to be used in phase compensating the equalized signal.

The equalizer 301 may include a feedforward filter 310, an adder 320, a feedback filter 330, a decision unit 340, an error calculation unit 350, and two complex conjugate multipliers 360 and 370.

The decision unit 340 may decide which data is mapped to the equalized signal, and the error calculation unit 350 may calculate an error by comparing the data, which is mapped to the equalized signal with a corresponding constellation point.

The feedforward filter 310 and the feedback filter 330 may process the input signal without phase error compensation. Complex conjugate multipliers 360 and 370 counter-compensate for the phase of the output signals of the decision unit 340 and the error calculation unit 350.

FIG. 4 is a block diagram illustrating another conventional equalizing device including a phase-tracking loop and an equalizer. As shown, the equalizing device 400 may include an equalizer 401 and a phase-tracking loop 402, which cooperate with each other. The equalizer 401 may equalize an input signal, while the phase tracking loop 402 compensates for a phase error of the input signal. The equalization and the phase compensation may be performed simultaneously. The equalizer 401 may include a feedforward filter 410, an adder 420, a feedback filter 430, a decision unit 440, an error calculation unit 450, a complex conjugate multiplier 470, and a complex multiplier 480.

When an I-signal and a Q-signal included in an input complex signal do not have phase and/or amplitude imbalances, data mapped to the input complex signal may be obtained using a conventional equalizing device, for example, as shown in FIGS. 2-4. However, data mapped to the input complex signal may not be effectively obtained when phase and/or amplitude imbalances are present in the input complex signal. Example effects of the phase imbalance will be discussed in more detail below with reference to FIG. 5A and FIG. 5B, and example effects of the amplitude imbalance will be discussed in more detail with reference to FIG. 6A and FIG. 6B.

FIGS. 5A and 5B are diagrams illustrating an example effect of a phase imbalance in a QAM constellation. As shown, constellation ‘A’ represents an arrangement of output signals of the equalizer without phase imbalance, and constellation ‘B’ represents an arrangement of output signals of the equalizer with phase imbalance. When phase imbalance exists, the I-signal and the Q-signal may be analyzed as a signal different from an original signal, and the equalized complex signal may be mapped to the wrong data, (e.g., data different from original data).

An example effect of the phase imbalance is explained below assuming the I-signal and the Q-signal have a value of 3. When phase imbalance as shown in FIG. 5A exists, both values of the I-signal and the Q-signal may be less than 3. On the contrary, when a phase imbalance as shown in FIG. 5B exists, values of the I-signal and the Q-signal may be greater than 3.

FIG. 6A and FIG. 6B are diagrams illustrating an effect of an amplitude imbalance in a QAM constellation.

Referring to FIG. 6A and FIG. 6B, constellation ‘C’ represents an arrangement of output signals from the equalizer without amplitude imbalance, and constellation ‘D’ represents an arrangement of output signals of the equalizer with amplitude imbalance. When amplitude imbalance exists, the I-signal and the Q-signal may be analyzed as a signal different from an original signal, and the equalized complex signal may be mapped to the wrong data (e.g., data different from original data).

An example effect of the amplitude imbalance is explained below assuming that the I-signal and the Q-signal have a value of 3. When amplitude imbalance as shown in FIG. 6A exists, the value of the I-signal may be less than 3 and the value of the Q-signal may be greater than 3. When amplitude imbalance as shown in FIG. 6B exists, the value of the I-signal may be greater than 3 and the value of the Q-signal may be less than 3.

The phase and/or amplitude imbalance(s) may be reduced by increasing a signal-to-noise ratio (SNR). However, higher output power of a transmitter may be required to increase the SNR, and the output power of the transmitter may be limited by wireless communication standards.

### SUMMARY OF THE INVENTION

Example embodiments of the present invention provide methods and apparatuses for processing complex signals, in which phase and/or amplitude imbalances of complex signals may be compensated.

Example embodiments of the present invention provide methods and apparatuses for compensating for a phase imbalance of a complex signal.

Example embodiments of the present invention provide methods and apparatuses for compensating for an amplitude imbalance of a complex signal.

In at least one example embodiment of the present invention, at least one complex signal may include a first channel signal (e.g., an in-phase channel signal (I-signal)) and a second channel (e.g., quadrature channel signal (Q-signal)). The second channel signal may be perpendicular to the first channel signal. The at least one complex signal may be equalized and a phase error of the complex signal may be compensated. A phase imbalance and/or an amplitude imbalance between the first channel signal and the second channel signal may be compensated, and the compensated complex signal may be output as an output complex signal.

Another example embodiment of the present invention provides an apparatus for processing at least one complex signal. The at least one complex signal may include a first channel signal and a second channel signal, and the second channel signal may be perpendicular to the first channel signal. The apparatus may include an equalizer, a phase-tracking loop and/or an imbalance compensator. The equalizer may be configured to equalize the at least one complex signal. The phase-tracking loop may be configured to compensate for a phase error of the at least one complex signal. The imbalance compensator may be configured to compensate for at least one of a phase imbalance and an amplitude imbalance between the first channel signal and the second channel signal, and output an output complex signal.

At least one example embodiment of the present invention provides a method of compensating for a phase imbalance of at least one complex signal. The at least one complex signal may include a first channel signal and a second channel signal, and the second channel signal may be perpendicular to the first channel signal. A phase imbalance compensation coefficient for the at least one complex signal may be calculated and a phase imbalance of the first channel signal may be compensated for based on a product of the second channel signal and the phase imbalance compensation coefficient. A phase imbalance of the second channel signal may be compensated for based on a product of the first channel signal and the phase imbalance compensation coefficient.

At least one other example embodiment of the present invention provides an apparatus for compensating for a phase imbalance of at least one complex signal. The apparatus may include a phase imbalance calculator, a first compensator and a second compensator. The phase imbalance calculator may be configured to calculate a phase imbalance compensation coefficient for the at least one complex signal. The first compensator may be configured to compensate for a first channel signal based on a product of the second channel signal and the phase imbalance compensation coefficient. The second compensator may be configured to compensate for the second channel signal based on a product of the first channel signal and the phase imbalance compensation coefficient.

At least one other example embodiment of the present invention provides a method for compensating for an amplitude imbalance of at least one complex signal. An amplitude imbalance of the first channel signal and/or the second channel signal may be compensated for based on the amplitude imbalance compensation coefficient.

At least one other example embodiment of the present invention provides an apparatus for compensating for an amplitude imbalance of at least one complex signal. The apparatus may include an amplitude imbalance calculator, a first calculator and/or a second calculator. The amplitude imbalance calculator may be configured to calculate an amplitude imbalance compensation coefficient for the at least one complex signal. The first compensator may be configured to compensate for the first channel signal based on the amplitude imbalance compensation coefficient, and the second compensator may be configured to compensate for the second channel signal based on the amplitude imbalance compensation coefficient.

In at least some example embodiments of the present invention, the phase error of the input complex signal may be compensated based on a previously output phase and/or amplitude imbalance compensated complex signal.

In at least one example embodiment of the present invention, the imbalance compensator may include a phase imbalance compensator and/or an amplitude imbalance compensator. The phase imbalance compensator may be configured to compensate for a phase imbalance of the equalized complex signal. The amplitude imbalance compensator may be configured to compensate for an amplitude imbalance of the phase imbalance compensated complex signal.

In at least some example embodiments of the present invention, a phase imbalance of the equalized input complex signal may be compensated, and then a amplitude imbalance of the phase imbalance compensated complex signal may be compensated.

According to at least some example embodiments of the present invention, a phase imbalance compensation coefficient may be calculated, and the phase imbalance of first channel signal may be compensated based on a product of the second channel signal and the phase imbalance compensation coefficient. The phase imbalance of the second channel signal may be compensated based on a product of the first channel signal and the phase imbalance compensation coefficient. In calculating the phase imbalance compensation coefficient, a phase imbalance coefficient may be calculated based on a previously output phase and/or amplitude imbalance compensated complex signal. The phase imbalance coefficient may be accumulated to calculate the phase imbalance compensation coefficient. The previously output phase and/or amplitude compensated complex signal may include a previously output phase and/or amplitude compensated first channel signal and second channel signal.

According to at least some example embodiments of the present invention, the phase imbalance coefficient may be calculated by multiplying the previously output phase and/or amplitude compensated first channel signal by the previously output phase and/or amplitude compensated second channel signal, and multiplying the product by a step-size coefficient to calculate the phase imbalance coefficient.

In at least some example embodiments of the present invention, the amplitude imbalance may be compensated by calculating an amplitude imbalance compensation coefficient, compensating for the first channel signal based on the amplitude imbalance compensation coefficient, and compensating for second channel signal based on the amplitude imbalance compensation coefficient. The amplitude imbalance compensation coefficient may be calculated by calculating an amplitude imbalance coefficient based on a previously output phase and/or amplitude compensated complex signal, and accumulating the amplitude imbalance coefficient to calculate the amplitude imbalance compensation coefficient.

According to at least some example embodiments of the present invention, calculating the amplitude imbalance coefficient may include subtracting an absolute value of a previously output phase and/or amplitude compensated second channel signal from an absolute value of a previously output phase and/or amplitude compensated first channel signal, and multiplying the difference by a step-size coefficient to calculate the amplitude imbalance coefficient.

In at least some example embodiments of the present invention, the amplitude imbalance of the equalized complex signal may be compensated, and then the phase imbalance of the amplitude imbalance compensated complex signal may be compensated.

According to at least some example embodiments of the present invention, the phase-tracking loop may compensate for the phase error of the input complex signal based on a previously output phase and/or amplitude imbalance compensated complex signal.

In at least some example embodiments of the present invention, the phase imbalance compensator may include a phase imbalance calculator, a first compensator and a second compensator. The phase imbalance calculator may be configured to calculate a phase imbalance compensation coefficient. The first compensator may be configured to compensate for the first channel signal based on a product of the second channel signal and the phase imbalance compensation coefficient. The second compensator may be configured to compensate for the second channel signal based on a product of the first channel signal and the phase imbalance compensation coefficient.

A phase imbalance calculator, according to at least one example embodiment of the present invention, may include a first calculator and an accumulator. The first calculator may be configured to calculate a phase imbalance coefficient based on a previously output imbalance compensated complex signal, and the accumulator may be configured to accumulate the phase imbalance coefficient to calculate the phase imbalance compensation coefficient. The first calculator may include a signal multiplier and a step-size multiplier. The signal multiplier may be configured to multiply the previously output imbalance compensated first channel signal and the previously output imbalance compensated second channel signal, and the step-size multiplier may be configured to multiply the product by a step-size coefficient to calculate the phase imbalance coefficient.

An amplitude imbalance compensator, according to at least one example embodiment of the present invention, may include an amplitude imbalance calculator, a third compensator and a fourth compensator. The amplitude imbalance compensator may be configured to calculate an amplitude imbalance compensation coefficient. The third compensator may be configured to compensate for an amplitude imbalance of the first channel signal based on the amplitude imbalance compensation coefficient. The fourth compensator may be configured to compensate for an amplitude imbalance of the second channel signal based on the amplitude imbalance compensation coefficient.

An amplitude imbalance calculator, according to at least one example embodiment of the present invention, may include a second calculator and an accumulator. The second calculator may be configured to calculate an amplitude imbalance coefficient based on a previously output imbalance compensated complex signal. The accumulator may be configured to accumulate the amplitude imbalance coefficient to calculate the amplitude imbalance compensation coefficient. The second calculator may include a subtractor and a step-size multiplier. The subtractor may be configured to subtract an absolute value of the second channel signal from an absolute value of the first channel signal. The step-size multiplier may be configured to multiply the difference by a step-size coefficient to calculate the amplitude imbalance coefficient.

In at least one other example embodiment of the present invention, the imbalance compensator may include an amplitude imbalance compensator and a phase imbalance compensator. The amplitude imbalance compensator may be configured to compensate for the amplitude imbalance of the equalized complex signal, and the phase imbalance compensator may be configured to compensate for the phase imbalance of the amplitude imbalance compensated complex signal.

Calculating the amplitude imbalance compensation coefficient may include calculating an amplitude imbalance coefficient based on a previously output amplitude and/or phase imbalance compensated signal. The amplitude imbalance coefficient may be accumulated to calculate the amplitude imbalance compensation coefficient. The amplitude imbalance coefficient may be calculated by subtracting an absolute value of a second channel signal from an absolute value of a first channel signal, wherein the first and second channel signals are included in the previously output amplitude and/or phase imbalance compensated signal. The difference may be multiplied by a step-size coefficient to calculate the amplitude imbalance coefficient.

An amplitude imbalance calculator, according to at least one example embodiment of the present invention, may include a first calculator, a previously output amplitude and/or phase compensated complex signal, and an accumulator configured to accumulate the amplitude imbalance coefficient to calculate the amplitude imbalance compensation coefficient. The first calculator may include a signal subtractor and/or a step-sized multiplier. The subtractor may be configured to subtract an absolute value of the second channel signal from an absolute value of the first channel signal, and a step-size multiplier configured to multiply the difference by a step-size coefficient to calculate the amplitude imbalance coefficient.

### BRIEF DESCRIPTION OF THE DRAWINGS

The present invention will be described in detail with reference to the example embodiments illustrated in the drawings, in which:

FIG. 1 is a diagram illustrating a 64-QAM signal constellation;

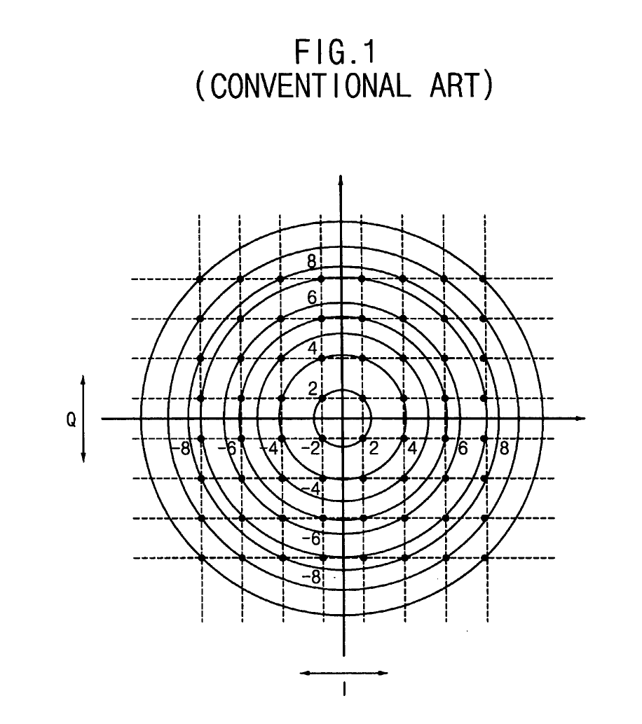

FIG. 2 is a block diagram illustrating a conventional equalizing device;

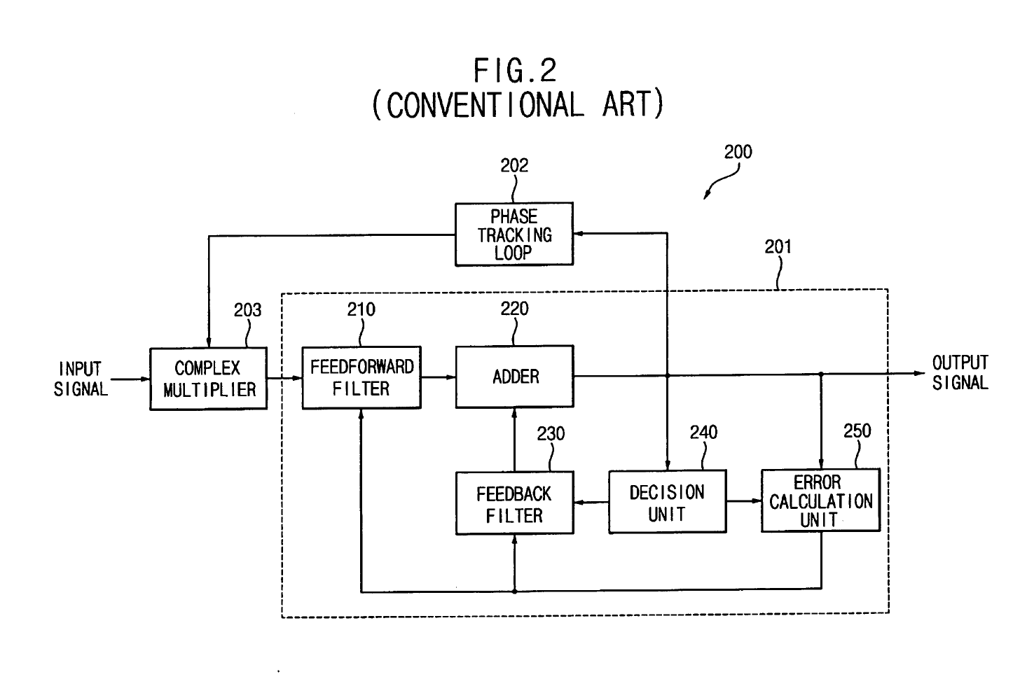

FIG. 3 is a block diagram illustrating another conventional equalizing device;

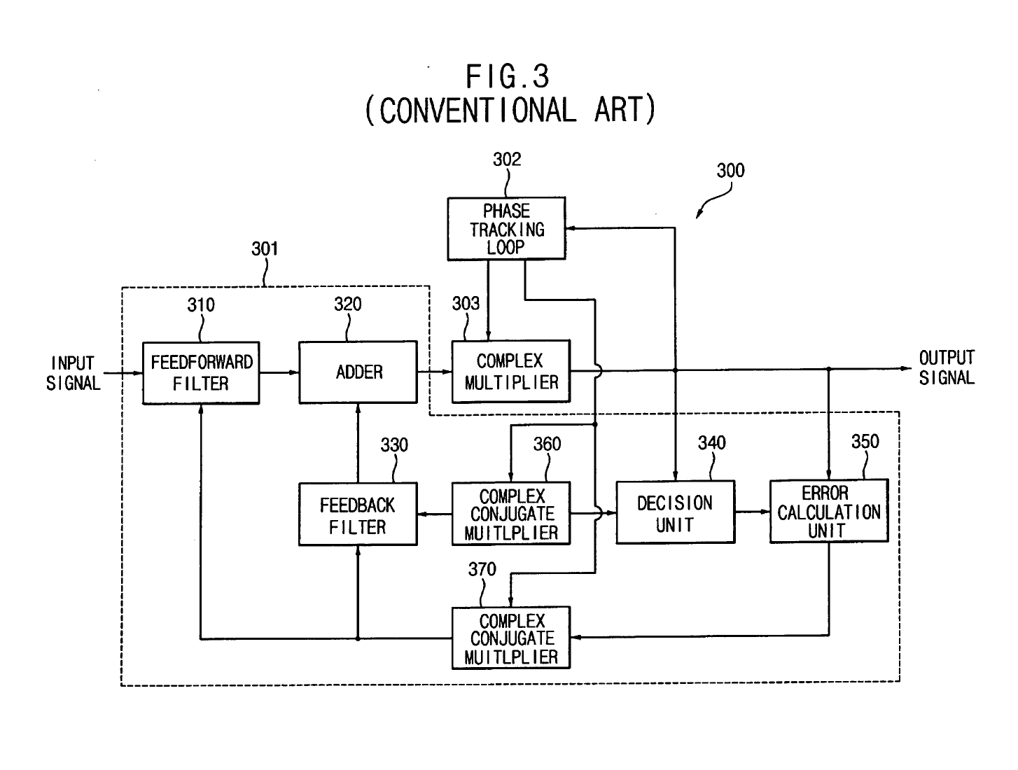

FIG. 4 is a block diagram illustrating another conventional equalizing device;

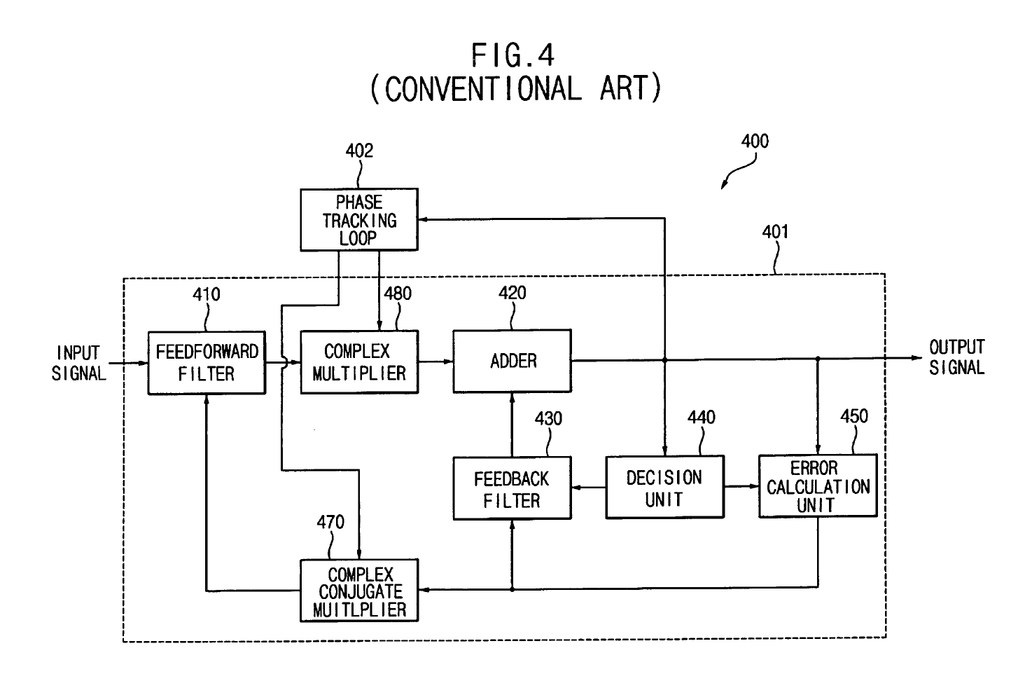

FIGS. 5A and 5B are diagrams illustrating an effect of a phase imbalance in a QAM constellation;

FIGS. 6A and 6B are diagrams illustrating an effect of an amplitude imbalance in a QAM constellation;

FIG. 7 is a block diagram illustrating an apparatus for processing complex signals, according to an example embodiment of the present invention;

FIG. 8 is a diagram illustrating a phase imbalance compensator according, to an example embodiment of the present invention;

FIG. 9 is a diagram illustrating an amplitude imbalance compensator, according to an example embodiment of the present invention;

FIG. 10 is a block diagram illustrating an apparatus for processing complex signals, according to another example embodiment of the present invention;

FIG. 11 is a flow chart illustrating a method of processing complex signals, according to an example embodiment of the present invention;

FIG. 12 is a flow chart illustrating a method of compensating for a phase imbalance, according to an example embodiment of the present invention; and

FIG. 13 is a flow chart illustrating a method of compensating for an amplitude imbalance, according to an example embodiment of the present invention.

### DETAILED DESCRIPTION OF EXAMPLE EMBODIMENTS OF THE PRESENT INVENTION

Example embodiments of the present invention are disclosed herein. However, specific structural and functional details disclosed herein are merely representative for purposes of describing example embodiments of the present invention. Rather, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Although example embodiments of the present invention may be described herein with respect to processing complex signals, it will be understood that complex signals may include at least one or a plurality of complex signals. In addition, although example embodiments of the present invention may be described herein with respect to compensating for phase or amplitude imbalance, it will be understood that example embodiments of the present invention may be used to compensate for amplitude or phase imbalance of a complex input signal.

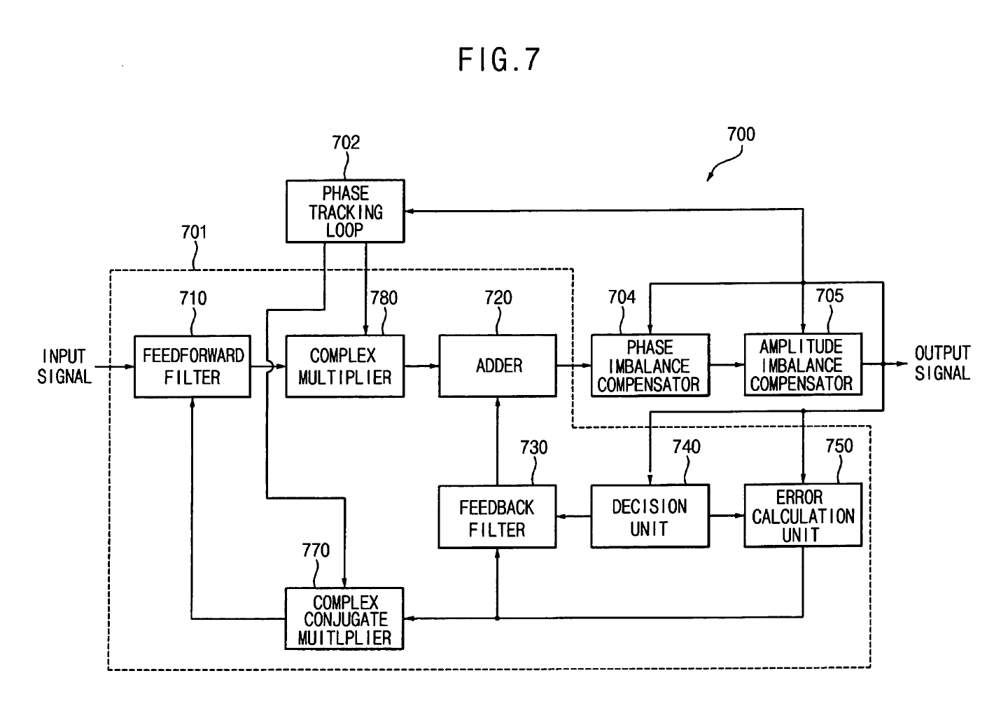

FIG. 7 is a block diagram illustrating an apparatus for processing complex signals, according to an example embodiment of the present invention.

Referring to FIG. 7, the apparatus 700 may include an equalizer 701, a phase-tracking loop 702, a phase imbalance compensator 704, and/or an amplitude imbalance compensator 705.

The equalizer 701 and the phase-tracking loop 702 may compensate for a phase error of an input signal to equalize the input signal. The input signal may include an I-signal and a Q-signal that is perpendicular to the I-signal.

The equalizer 701 may include a feedforward filter 710, an adder 720, a feedback filter 730, a decision unit 740, an error calculation unit 750, a complex conjugate multiplier 770, and/or a complex multiplier 780.

The feedforward filter 710 may filter the input signal. The complex multiplier 780 may compensate for the phase error of the filtered signal by multiplying the filtered signal by a phase compensation value. The complex multiplier 780 may receive the phase compensation value from the phase-tracking loop 702. The phase-tracking loop 720 may calculate the phase compensation value based on information associated with the output signal, information regarding the output signal and/or the output signal itself, associated with, regarding or an output signal. The output signal may be phase imbalance and/or amplitude imbalance compensated.

The adder 720 may generate the equalized output signal by adding an output of the feedforward filter 710 and an output of the feedback filter 730.

The phase imbalance compensator 704 may compensate for the phase imbalance of the equalized signal output from the adder 720. The amplitude imbalance compensator 705 may compensate for the amplitude imbalance of the signal, which has been phase imbalance compensated, for example, by the phase imbalance compensator 704.

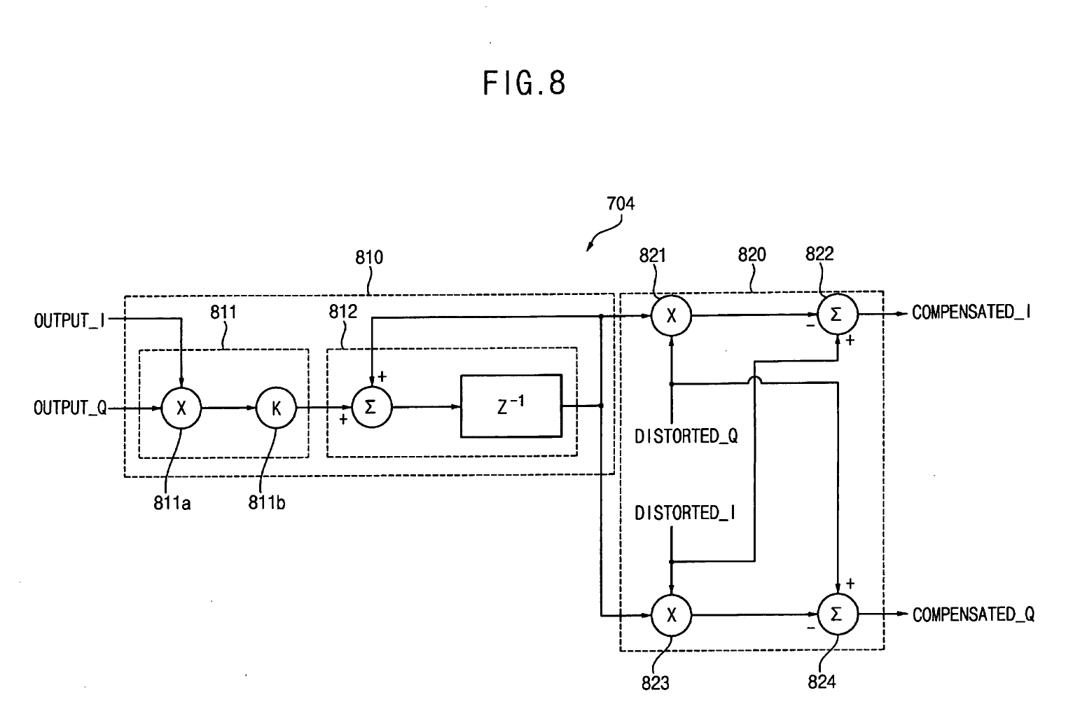

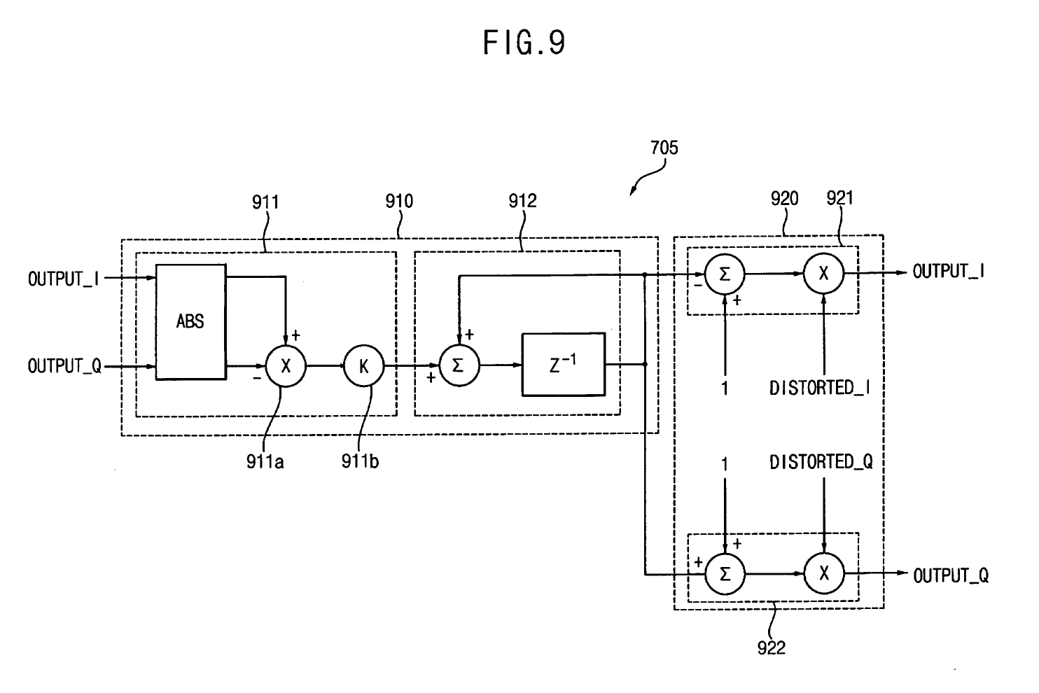

The output signal, which has been phase and amplitude compensated by the phase and amplitude compensators 704 and 705, respectively, may be used to compensate for the phase imbalance and the amplitude compensation of a subsequent input signal. In other words, the output signal may be fed back and used in compensating subsequent signals. The phase imbalance compensator 704 and the amplitude imbalance compensator 705 will be described in more detail below with reference to FIG. 8 and FIG. 9.

The decision unit 740 may decide which data is mapped to the phase and amplitude compensated output signal. The error calculation unit 750 may calculate an error of the output signal.

In at least some example embodiments, the error calculation unit 750 may calculate the error of the output signal through algorithms such as a constant modular algorithm (CMA), a decision-direct algorithm (DDA) or any other suitable algorithm.

In an initial CMA stage, the equalizer 701 may compensate a channel signal, and the channel signal may be converged through a subsequent DDA stage. Methods for channel compensation are well-known in the art, and therefore, a detailed discussion thereof is omitted for the sake of brevity.

The complex conjugate multiplier 770 may counter-compensate for the phase of the output signal, such that the compensation by the complex conjugate multiplier 770 opposes the phase error compensation by the complex multiplier 780. The counter-compensated output signal may be output to the feedforward filter 710.

FIG. 8 illustrates an apparatus for compensating for a phase imbalance of complex signals, according to an example embodiment of the present invention.

Referring to FIG. 8, the phase compensation apparatus 704 may include a phase imbalance calculator 810 and/or a phase imbalance compensation circuit 820. The phase imbalance calculator 810 may calculate a phase imbalance compensation coefficient, and the phase imbalance compensation circuit 820 may compensate for signals distorted by the phase imbalance. The phase imbalance calculator 810 may include a first calculator 811 and/or an accumulator 812. The first calculator 811 may calculate a phase imbalance coefficient, and the accumulator 812 may accumulate the phase imbalance coefficient. The phase imbalance compensation circuit 820 may include two compensators that may compensate for an I-signal and a Q-signal, respectively. Each of the compensators may include a respective signal multiplier 821 or 823 and a respective subtractor 822 or 824.

A signal multiplier 811a may be included in the first calculator 811. The signal multiplier 811a may multiply the I-signal and the Q-signal, when the I-signal and the Q-signal are included in a previous output signal, which has been phase and/or amplitude compensated. A step-size multiplier 811b may also include in the first calculator 811. The step-size multiplier 811b may multiply the output of the signal multiplier 811a by a step-size coefficient. When the step-size coefficient is a smaller value (e.g., about 0.01), a swing range of the phase imbalance coefficient may be decreased. For example, when the product varies from about −49 to about +49, inclusive, the phase imbalance coefficient may vary from about −0.49 to about +0.49, inclusive.

The accumulator 812 may accumulate the phase imbalance coefficient to calculate the phase imbalance compensation coefficient. The phase imbalance compensation coefficient may be a positive value or a negative value according to a phase imbalance type of the I-signal and the Q-signal. A degree of the phase imbalance compensation coefficient may increase as the phase imbalance increases.

The phase imbalance compensation coefficient may indicate the type and/or degree of the phase imbalance. The I-signal and the Q-signal may have one value of −7, −5, −3, −1, 1, 3, 5, and 7, respectively, when there no phase imbalance is present. When the I-signal and the Q-signal has phase imbalance, the I-signal and the Q-signal may have a value greater than or less than one of −7, −5, −3, −1, 1, 3, 5, and 7, respectively,

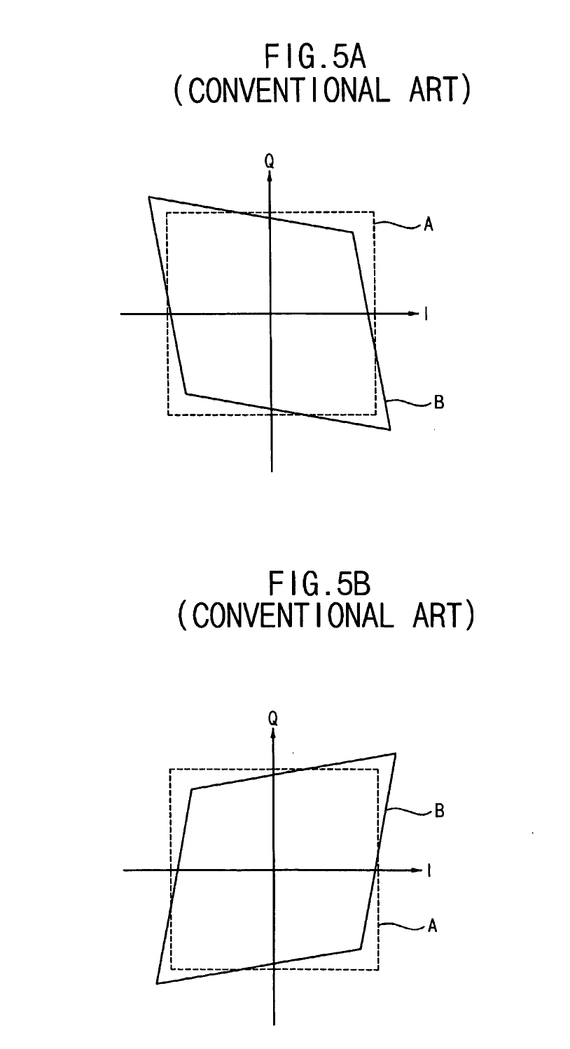

For example, the phase imbalance of FIG. 5A is present, absolute values of the I-signal and the Q-signal in the first and third quadrants may be smaller than those without phase imbalance, and absolute values of the I-signal and the Q-signal in the second and fourth quadrants may be greater than those without phase imbalance. When a complex signal exists in the first or third quadrants, the product of the I-signal multiplied by the Q-signal may be positive. On the other hand, when a complex signal is present in the second or fourth quadrants, the product of the I-signal multiplied by the Q-signal may be negative. In one example where the phase imbalance of FIG. 5A is present, an average of the products may be negative, and the accumulator 812 may output a negative phase imbalance compensation coefficient.

When the phase imbalance of FIG. 5B exists, absolute values of the I-signal and the Q-signal in the first and third quadrants may be greater than those without phase imbalance, and absolute values of the I-signal and the Q-signal in the second and fourth quadrants may be smaller than those without phase imbalance. When a complex signal is present in the first or third quadrants, the product of the I-signal multiplied by the Q-signal may be positive. On the other hand, when a complex signal is present in the second or fourth quadrants, the product of the I-signal multiplied by the Q-signal may be negative. In an example where the phase imbalance of FIG. 5B exists, an average of the products may be positive, and the accumulator 812 may output a positive phase imbalance compensation coefficient.

An absolute value of the phase imbalance compensation coefficient may be proportional to the degree of the phase imbalance. In the complex signal with phase imbalance, the I-signal error and the Q-signal error may be proportional to one another. For example, the I-signal error may be proportional to the Q-signal, and the Q-signal error may be proportional to the I-signal. In this example, the phase imbalance compensation circuit 820 may compensate for the phase imbalance of the distorted signals using Equation 1:

$$Compensated\_I = Distorted\_I + Distorted\_Q \times x \\ Compensated\_Q = Distorted\_Q + Distorted\_I \times x \qquad [ Equation 1 ]$$

In Equation 1, Distorted_I and Distorted_Q may represent the I-signal and the Q-signal portions of the phase imbalanced complex signal, respectively. Compensated_I and Compensated_Q represent the compensated I-signal and the compensated Q-signal, respectively. “x” represents the phase imbalance compensation coefficient.

FIG. 9 is a diagram illustrating an amplitude imbalance compensator, according to an example embodiment of the present invention.

Referring to FIG. 9, the amplitude imbalance compensation apparatus 704 may include an amplitude imbalance calculator 910 and/or an amplitude imbalance compensation circuit 920. The amplitude imbalance calculator 910 may calculate an amplitude imbalance compensation coefficient, and the amplitude imbalance compensation circuit 920 may compensate for signals distorted by the amplitude imbalance.

The amplitude imbalance calculator 910 may include a second calculator 911 and/or an accumulator 912. The second calculator 911 may calculate an amplitude imbalance coefficient, and the accumulator 912 may accumulate the amplitude imbalance coefficient. The amplitude imbalance compensation circuit 920 may include two compensators 921 and 922. Each one of the two compensators may compensate for respective one of an I-signal and a Q-signal.

A signal subtractor 911b, that may be included in the second calculator 911, may subtract an absolute value of the I-signal from an absolute value of the Q-signal where the I-signal and the Q-signal are portions of a previously compensated output signal. A step-size multiplier 911b, which may also be included in the first calculator 911, may multiply the difference by a step-size coefficient K. When the step-size coefficient K has a smaller value (e.g., about 0.05), a swing range of the amplitude imbalance coefficient may be decreased. For example, when the product varies from about −49 to about +49, inclusive, the amplitude imbalance coefficient may vary from about −0.35 to about +0.35, inclusive.

The accumulator 912 may accumulate the amplitude imbalance coefficient to calculate the amplitude imbalance compensation coefficient. The amplitude imbalance compensation coefficient may be a positive or a negative value based on the type of amplitude imbalance. For example, a degree of the amplitude imbalance compensation coefficient may increase as the amplitude imbalance increases.

The amplitude imbalance compensation coefficient may indicate the type and/or the degree of the amplitude imbalance. The I-signal and the Q-signal may have a value of −7, −5, −3, −1, 1, 3, 5, and 7, respectively, without amplitude imbalance. When the I-signal and the Q-signal has amplitude imbalance, the I-signal and the Q-signal may have a value greater than or less than one of −7, −5, −3, −1, 1, 3, 5, and 7.

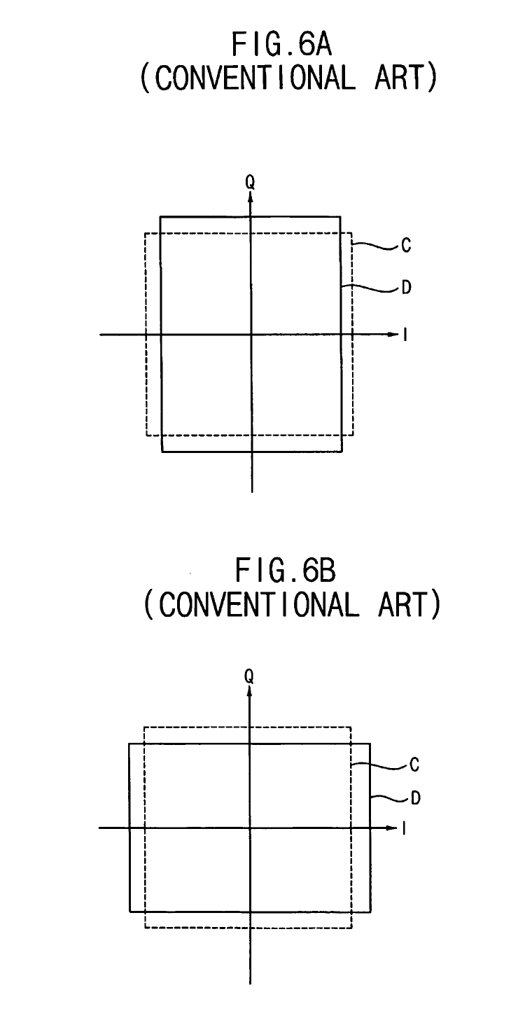

When the amplitude imbalance of FIG. 6A exists, an absolute value of the I-signal may be smaller than the absolute value of the I-signal without amplitude imbalance, and an absolute value of the Q-signal may be greater than the absolute value of the Q-signal without amplitude imbalance. In this example, an average of the differences may be negative, and the accumulator 912 may output a negative amplitude imbalance compensation coefficient.

When the amplitude imbalance of FIG. 6B exists, an absolute value of the I-signal may be greater than the absolute value of the I-signal without amplitude imbalance, and an absolute value of the Q-signal may be smaller than the absolute value of the Q-signal without amplitude imbalance. In this example, an average of the differences may be positive, and the accumulator 912 may output a positive amplitude imbalance compensation coefficient.

An absolute value of the amplitude imbalance compensation coefficient may be proportional to the degree of the amplitude imbalance, and the amplitude imbalance compensation circuit 920 may compensate for the amplitude imbalance of the distorted signals using Equation 2:

$$Output\_I = Compensated\_I \times ( 1 - y ) \\ Output\_Q = Compensated\_Q \times ( 1 + y ) \qquad [ Equation 2 ]$$

In Equation 2, Compensated_I and Compensated_Q represent the amplitude compensated I-signal and the amplitude compensated Q-signal, respectively. Output_I and Output_Q represent the phase and amplitude compensated I-signal and the phase and amplitude compensated Q-signal, and “y” represents the amplitude imbalance compensation coefficient.

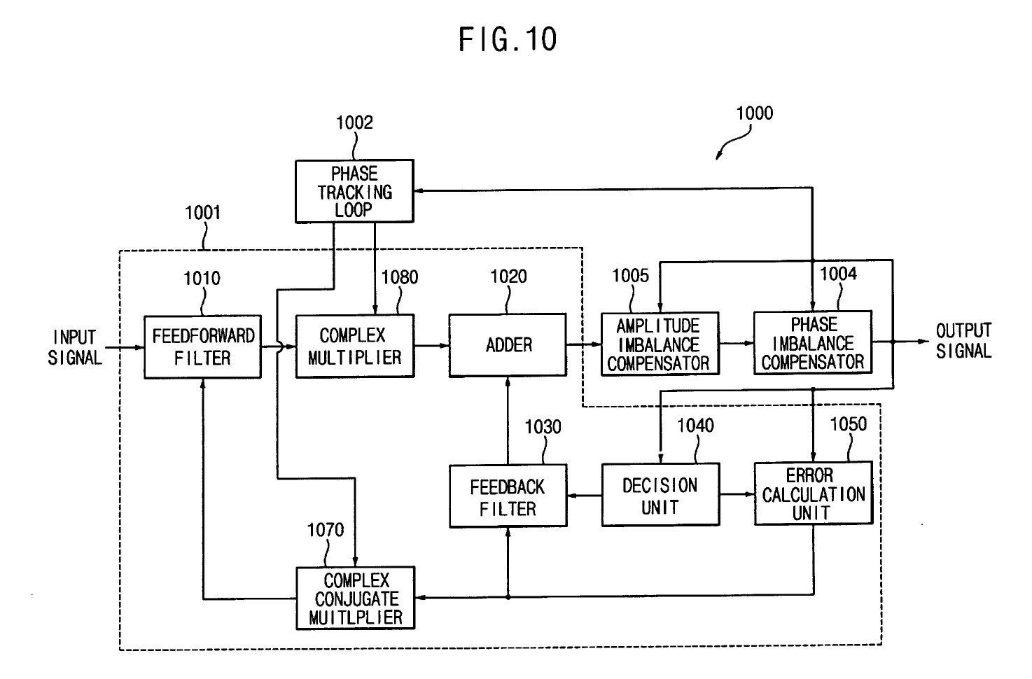

FIG. 10 is a block diagram illustrating an apparatus for processing complex signals, according to another example embodiment of the present invention.

Referring to FIG. 10, the apparatus 1000 may include an equalizer 1001, a phase-tracking loop 1002, a phase imbalance compensator 1004, and/or an amplitude imbalance compensator 1005.

The equalizer 1001 and the phase-tracking loop 1002 may cooperate or work in conjunction with one another to compensate for a phase error of an input signal, which may equalize the input signal. The input signal may include an I-signal and a Q-signal that is perpendicular to the I-signal.

The equalizer 1001 may include a feedforward filter 1010, an adder 1020, a feedback filter 1030, a decision unit 1040, an error calculation unit 1050, a complex conjugate multiplier 1070, and/or a complex multiplier 1080. The elements of the equalizer 1001 may be the same or substantially the same as those of the equalizer 701 of FIG. 7, and thus, a detailed description of these elements will be omitted for the sake of brevity.

The apparatus 1000 of FIG. 10 may compensate for the amplitude imbalance and for the phase imbalance successively. The phase imbalance compensator 1004 and/or the amplitude imbalance compensator 1005 may be configured in the same or substantially the same manner as the phase imbalance compensator 704 of FIG. 8 and/or the amplitude imbalance compensator 705 of FIG. 9, respectively. The amplitude imbalance compensator 1005 may receive an input signal that has both phase and amplitude imbalances. The phase imbalance compensator 1004 may receive an amplitude compensated input signal. The amplitude compensated signal may be a signal for which the amplitude imbalance has been compensated, and has only the phase imbalance.

The apparatuses of FIG. 7 and FIG. 10 may include an equalizer, a phase-tracking loop, and an imbalance compensator, respectively. However, the imbalance compensator of FIG. 7 may compensate for the phase imbalance and then the amplitude imbalance, whereas the imbalance compensator of FIG. 10 may compensate for the amplitude imbalance and then the phase imbalance.

It will be understood to those skilled in the art that an apparatus for processing complex signals, according to example embodiments of the present invention, may be configured such that the phase imbalance and the amplitude imbalance may be compensated simultaneously, concurrently, at the same time, etc.

Although example embodiments of the present invention have been described with regard to phase and amplitude imbalance compensation, example embodiments of the present invention may also provide one or more imbalance compensators that compensate for one of the I-signal and the Q-signal.

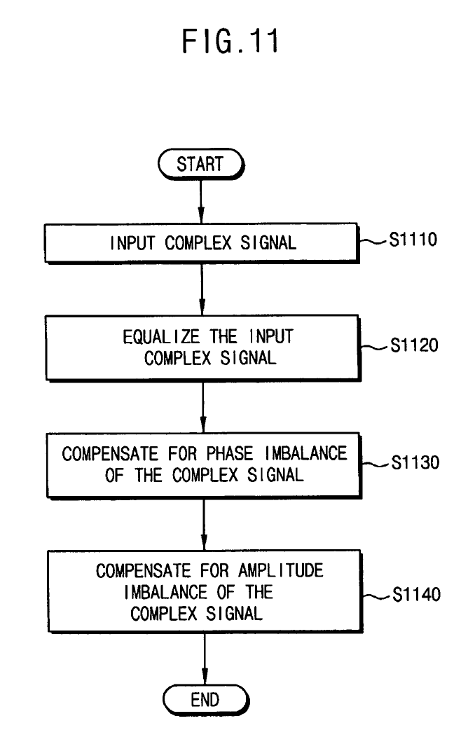

FIG. 11 a flow chart illustrating a method of processing complex signals, according to an example embodiment of the present invention. Referring to FIG. 11, a complex signal may be input at S1110. The complex signal may include two signals (e.g., I-signal and Q-signal) perpendicular to each other.

After the complex signal is input, the input signal may be equalized and the phase error may be compensated at S1120.

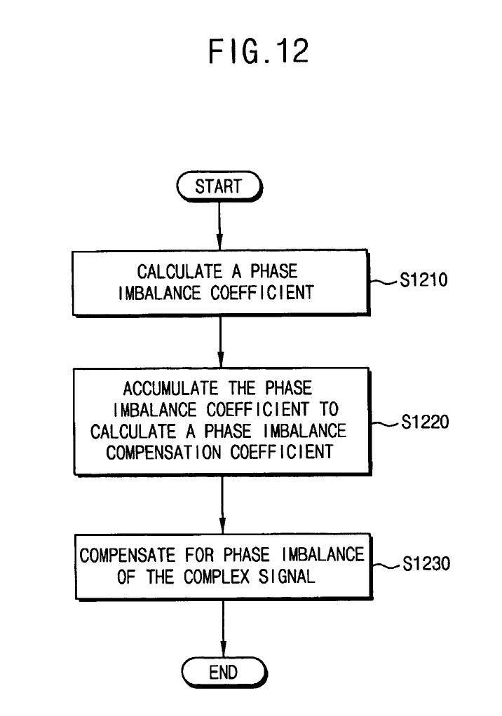

After the input signal is equalized, a phase imbalance of the equalized complex signal may be compensated at S1130. The compensation for the phase imbalance will be described in more detail below with regard to FIG. 12.

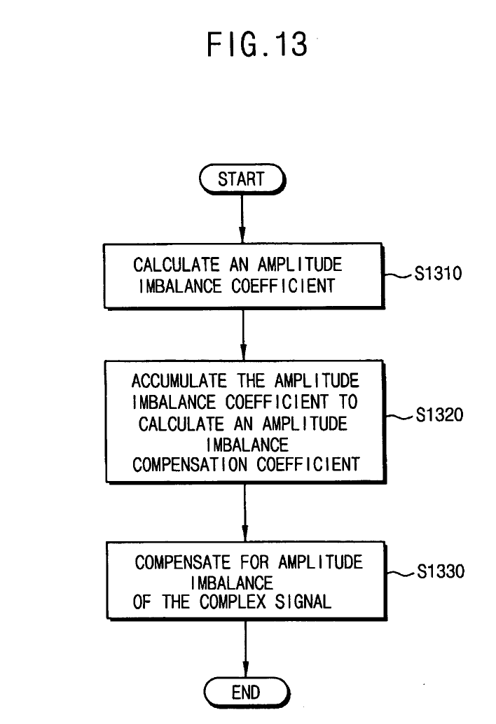

After the phase imbalance is compensated, an amplitude imbalance may be compensated at S1140. The compensation for the amplitude imbalance will be described in more detail below with regard to FIG. 13.

Although the above example embodiment of the present invention has been described with regard to compensating for a phase imbalance after compensating for an amplitude imbalance, it will be understood that the order of amplitude and phase compensations may be exchanged and/or may be performed simultaneously, concurrently, at the same time, etc.

FIG. 12 is a flow chart illustrating a method of compensating for a phase imbalance, according to an example embodiment of the present invention.

Referring to FIG. 12, a phase imbalance coefficient may be calculated at S1210. The phase imbalance coefficient may be calculated based on I-signal and Q-signal portions of a previously phase and amplitude imbalance compensated output signal.

When the phase imbalance coefficient is obtained, the phase imbalance coefficient may be accumulated to calculate a phase imbalance compensation coefficient at S1220. The phase imbalance compensation coefficient may include information on of a type and/or degree of the phase imbalance. For example, the type of the phase imbalance may be determined based on the sign of the phase imbalance compensation coefficient, and the degree of the phase imbalance may be determined based on the magnitude of absolute value of the phase imbalance compensation coefficient.

Based on the calculated phase imbalance compensation coefficient, the phase imbalance of the complex signal may be compensated at S1230.

FIG. 13 is a flow chart illustrating a method of compensating for an amplitude imbalance, according to an example embodiment of the present invention.

Referring to FIG. 13, an amplitude imbalance coefficient may be calculated at S1310. The amplitude imbalance coefficient may be calculated based on an I-signal and Q-signal portions of a previously phase and amplitude compensated output signal.

When the amplitude imbalance coefficient is calculated, the amplitude imbalance coefficient may be accumulated to calculate an amplitude imbalance compensation coefficient at S1320. The amplitude imbalance compensation coefficient may include information on a type and/or a degree of the amplitude imbalance. For example, the type of the amplitude imbalance may be determined based on, the sign of the amplitude imbalance compensation coefficient, and the degree of the amplitude imbalance may be determined based on the magnitude of an absolute value of the amplitude imbalance compensation coefficient.

Based on the calculated amplitude imbalance compensation coefficient, the amplitude imbalance of the complex signal may be compensated at S1330.

Methods and/or apparatuses for processing complex signals according to at least some example embodiments of the present invention may enable wireless communication when signal-to-noise ratio (SNR) is reduced by compensating for phase and/or amplitude imbalances, which may not be compensated for be an equalizer and/or a phase-tracking loop.

Methods and/or apparatuses for compensating for the phase imbalance, according to at least some example embodiments of the present invention may compensate for phase imbalance of complex signals through a less complex algorithm and/or calculation.

Methods and apparatuses for compensating for amplitude imbalance, according to at least some example embodiments of the present invention may compensate for amplitude imbalance of complex signals through a less complex algorithm.

Example embodiments as described herein are illustrative of the present invention, and should not to be construed as limiting thereof. Although example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, the foregoing is illustrative of example embodiments of the present invention and is not to be construed as limited to the specific example embodiments disclosed herein, and that modifications to the disclosed example embodiments, as well as other example embodiments, are intended to be included within the scope of the appended claims. The present invention is defined by the following claims, with equivalents of the claims to be included therein.

What is claimed is:

1. A method for processing at least one complex signal comprising:
equalizing and compensating for a phase error of at least one input complex signal, the at least one input complex signal including a first channel signal and a second channel signal, the second channel signal being perpendicular to the first channel signal;
compensating for at least one of a phase imbalance and an amplitude imbalance between the first channel signal and the second channel signal to generate an imbalance compensated signal; and
outputting the imbalance compensated signal as an output complex signal.

2. The method of claim 1, wherein the phase error of the at least one input complex signal is compensated based on a previously output imbalance compensated signal.

3. The method of claim 1, wherein compensating for at least one of the phase imbalance and the amplitude imbalance of the complex signal includes,
compensating for the phase imbalance of the input complex signal, and
compensating for the amplitude imbalance of the phase imbalance compensated input complex signal.

4. The method of claim 3, wherein compensating for the phase imbalance includes,
calculating a phase imbalance compensation coefficient,
compensating for a phase imbalance of the first channel signal based on a product of the second channel signal and the phase imbalance compensation coefficient, and
compensating for a phase imbalance of the second channel signal based on a product of the first channel signal and the phase imbalance compensation coefficient.

5. The method of claim 4, wherein calculating the phase imbalance compensation coefficient includes,
calculating a phase imbalance coefficient based on a previously output imbalance compensated complex signal, and
calculating the phase imbalance compensation coefficient by accumulating the phase imbalance coefficient.

6. The method of claim 5, wherein the previously output imbalance compensated complex signal includes an imbalance compensated first channel signal and an imbalance compensated second channel signal, and the calculating the phase imbalance coefficient includes,
multiplying the imbalance compensated first channel signal and the imbalance compensated second channel signal to calculate a first product, and
multiplying the first product by a step-size coefficient to calculate the phase imbalance coefficient.

7. The method of claim 3, wherein the phase imbalance compensated complex signal includes a phase imbalance compensated first channel signal and a phase imbalance compensated second channel signal, and compensating for the amplitude imbalance includes,
calculating an amplitude imbalance compensation coefficient,
compensating for the amplitude imbalance of the phase imbalance compensated first channel signal based on the amplitude imbalance compensation coefficient, and
compensating for the amplitude imbalance of the phase imbalance compensated second channel signal based on the amplitude imbalance compensation coefficient.

8. The method of claim 7, wherein calculating the amplitude imbalance compensation coefficient includes,
calculating an amplitude imbalance coefficient based on a previously output imbalance compensated complex signal, and
calculating the amplitude imbalance compensation coefficient by accumulating the amplitude imbalance coefficient.

9. The method of claim 8, wherein previously output imbalance compensated complex signal includes an imbalance compensated first channel signal and an imbalance compensated second channel signal, and calculating the amplitude imbalance coefficient includes,
subtracting an absolute value of the imbalance compensated second channel signal from an absolute value of the previously imbalance compensated first channel signal to generate a first difference, and
multiplying the first difference by a step-size coefficient to calculate the amplitude imbalance coefficient.

10. The method of claim 1, wherein compensating for at least one of the phase imbalance and the amplitude imbalance of the equalized complex signal includes,
compensating for the amplitude imbalance of the equalized complex signal, and
compensating for the phase imbalance of the amplitude imbalance compensated complex signal.

11. An apparatus for processing at least one complex signal, the apparatus comprising:
an equalizer configured to equalize at least one input complex signal, the at least one input complex signal including a first channel signal and a second channel signal, the second channel signal being perpendicular to the first channel signal;
a phase-tracking loop configured to compensate for a phase error of the at least one input complex signal; and
an imbalance compensator configured to compensate for at least one of a phase imbalance and an amplitude imbalance between the first channel signal and the second channel signal to generate an imbalance compensated signal, and output the imbalance compensated signal.

12. The apparatus of claim 11, wherein the phase-tracking loop is configured to compensate for the phase error of the at least one input complex signal based on a previously output imbalance compensated complex signal.

13. The apparatus of claim 11, wherein the imbalance compensator includes,
a phase imbalance compensator configured to compensate for the phase imbalance of the at least one input complex signal, and
an amplitude imbalance compensator configured to compensate for the amplitude imbalance of the phase imbalance compensated complex signal.

14. The apparatus of claim 13, wherein the phase imbalance compensator includes,
a phase imbalance calculator configured to calculate a phase imbalance compensation coefficient,
a first compensator configured to compensate for a phase imbalance of the first channel signal based on a product of the second channel signal and the phase imbalance compensation coefficient, and
a second compensator configured to compensate for a phase imbalance of the second channel signal based on a product of the first channel signal and the phase imbalance compensation coefficient.

15. The apparatus of claim 14, wherein the phase imbalance calculator includes,
a first calculator configured to calculate a phase imbalance coefficient based on a previously output imbalance compensated complex signal, and
an accumulator configured to accumulate the phase imbalance coefficient to calculate the phase imbalance compensation coefficient.

16. The apparatus of claim 15, wherein the previously output imbalance compensated complex signal includes an imbalance compensated first channel signal and an imbalance compensated second channel signal, and the first calculator includes,
a signal multiplier configured to multiply the imbalance compensated first channel signal by the imbalance compensated second channel signal to calculate a first product, and
a step-size multiplier configured to multiply the first product by a step-size coefficient to calculate the phase imbalance coefficient.

17. The apparatus of claim 13, wherein the previously output imbalance compensated complex signal includes an imbalance compensated first channel signal and an imbalance compensated second channel signal, and the amplitude imbalance compensator includes,
an amplitude imbalance calculator configured to calculate an amplitude imbalance compensation coefficient,
a third compensator configured to compensate for the amplitude imbalance of the phase imbalance compensated first channel signal based on the amplitude imbalance compensation coefficient, and
a fourth compensator configured to compensate for the amplitude imbalance of the phase imbalance compensated second channel signal based on the amplitude imbalance compensation coefficient.

18. The apparatus of claim 17, wherein the amplitude imbalance calculator includes,
an amplitude imbalance calculator configured to calculate an amplitude imbalance coefficient based on the previously output imbalance compensated complex signal, and
an accumulator configured to accumulate the amplitude imbalance coefficient to calculate the amplitude imbalance compensation coefficient.

19. The apparatus of claim 18, wherein the previously output imbalance compensated complex signal includes an imbalance compensated first channel signal and an imbalance compensated second channel signal, and the amplitude imbalance calculator includes,
a subtractor configured to subtract an absolute value of the imbalance compensated second channel signal from an absolute value of the imbalance compensated first channel signal to generate a difference; and
a step-size multiplier configured to multiply the difference by a step-size coefficient to calculate the amplitude imbalance coefficient.

20. The apparatus of claim 11, wherein the imbalance compensator includes,
an amplitude imbalance compensator configured to compensate for the amplitude imbalance of the input complex signal, and
a phase imbalance compensator configured to compensate for the phase imbalance of the amplitude imbalance compensated signal.

21. A method for compensating for a phase imbalance of at least one complex signal, the method comprising:
calculating a phase imbalance compensation coefficient for the at least one complex signal, the at least one complex signal including a first channel signal and a second channel signal, the second channel signal being perpendicular to the first channel signal;
compensating for the phase imbalance of the first channel signal based on a product of the second channel signal and the phase imbalance compensation coefficient; and
compensating for the phase imbalance of the second channel signal based on a product of the first channel signal and the phase imbalance compensation coefficient.

22. The method of claim 21, wherein calculating the phase imbalance compensation coefficient includes,
calculating a phase imbalance coefficient based on a previously output imbalance compensated complex signal, and
calculating the phase imbalance compensation coefficient by accumulating the phase imbalance coefficient.

23. The method of claim 22, wherein the previously output imbalance compensated complex signal includes an imbalance compensated first channel signal and an imbalance compensated second channel signal, and the calculating the phase imbalance coefficient includes,
multiplying the imbalance compensated first channel signal and the imbalance compensated second channel signal to calculate a first product, and
multiplying the first product by a step-size coefficient to calculate the phase imbalance coefficient.

24. An apparatus for compensating for a phase imbalance of at least one complex signal, the apparatus comprising:
a phase imbalance calculator configured to calculate a phase imbalance compensation coefficient for the at least one complex signal, the at least one complex signal including a first channel signal and a second channel signal, the second channel signal being perpendicular to the first channel signal;
a first compensator configured to compensate for the phase imbalance of the first channel signal based on a product of the second channel signal and the phase imbalance compensation coefficient; and
a second compensator configured to compensate for the phase imbalance of the second channel signal based on a product of the first channel signal and the phase imbalance compensation coefficient.

25. The apparatus of claim 24, wherein the phase imbalance calculator includes,
a first calculator configured to calculate a phase imbalance coefficient based on a previously output imbalance compensated complex signal; and
an accumulator configured to accumulate the phase imbalance coefficient to calculate the phase imbalance compensation coefficient.

26. The apparatus of claim 25, wherein the previously output imbalance compensated complex signal includes an imbalance compensated first channel signal and an imbalance compensated second channel signal, and the first calculator includes,
a signal multiplier configured to multiply the imbalance compensated first channel signal and the imbalance compensated second channel signal to calculate a first product, and
a step-size multiplier configured to multiply the first product by a step-size coefficient to calculate the phase imbalance coefficient.

27. A method of compensating for an amplitude imbalance of at least one complex signal, the method comprising:
calculating an amplitude imbalance compensation coefficient for the at least one complex signal, the at least one complex signal including a first channel signal and a second channel signal, the second channel signal being perpendicular to the first channel signal;
compensating for an amplitude imbalance of the first channel signal based on the amplitude imbalance compensation coefficient; and
compensating for an amplitude imbalance of the second channel signal based on the amplitude imbalance compensation coefficient.

28. The method of claim 27, wherein calculating the amplitude imbalance compensation coefficient includes,
calculating an amplitude imbalance coefficient based on a previously imbalance compensated complex signal, and
accumulating the amplitude imbalance coefficient to calculate the amplitude imbalance compensation coefficient.

29. The method of claim 28, wherein the previously output amplitude imbalance compensated complex signal includes an imbalance compensated first channel signal and an amplitude imbalance compensated second channel signal, and calculating the amplitude imbalance coefficient includes,
subtracting an absolute value of the imbalance compensated second channel signal from an absolute value of the imbalance compensated first channel signal to calculate a difference, and
multiplying the difference by a step-size coefficient to calculate the amplitude imbalance coefficient.

30. The method of claim 27, wherein the first channel signal is compensated for using a first equation,
Compensated_{—}S1=(1−x)×S1,
where S1 is a magnitude of the first channel signal, Compensated_S1 is a magnitude of the amplitude imbalance compensated first channel signal, and x is the amplitude imbalance compensation coefficient.

31. The method of claim 27, wherein the second channel signal is compensated for using a second equation,
Compensated_{—}S2=(1+x)×S2,
where S2 is a magnitude of the second channel signal, Compensated_S2 is a magnitude of the amplitude imbalance compensated second channel signal, and x is the amplitude imbalance compensation coefficient.

32. An apparatus for compensating for an amplitude imbalance of at least one complex signal, the apparatus comprising:
an amplitude imbalance calculator configured to calculate an amplitude imbalance compensation coefficient for the at least one complex signal, the at least one complex signal including a first channel signal and a second channel signal, the second channel signal being perpendicular to the first channel signal;
a first compensator configured to compensate for an amplitude imbalance of the first channel signal based on the amplitude imbalance compensation coefficient; and
a second compensator configured to compensate for an amplitude imbalance of the second channel signal based on the amplitude imbalance compensation coefficient.

33. The apparatus of claim 32, wherein the amplitude imbalance calculator includes,
a first calculator configured to calculate an amplitude imbalance coefficient based on a previously imbalance compensated complex signal, and
an accumulator configured to accumulate the amplitude imbalance coefficient to calculate the amplitude imbalance compensation coefficient.

34. The apparatus of claim 33, wherein the previously output amplitude imbalance compensated complex signal includes an imbalance compensated first channel signal and an amplitude imbalance compensated second channel signal, and the first calculator includes,
a subtractor configured to calculate a difference by subtracting an absolute value of the imbalance compensated second channel signal from an absolute value of the imbalance compensated first channel signal to calculate a difference, and
a step-size multiplier configured to multiply the difference by a step-size coefficient to calculate the amplitude imbalance coefficient.

35. The apparatus of claim 32, wherein the first channel signal is compensated for using a first equation,
Compensated_{—}S1=(1−x)×S1,
where S1 is a magnitude of the first channel signal, Compensated_S1 is a magnitude of the amplitude imbalance compensated first channel signal, and x is the amplitude imbalance compensation coefficient.

36. The apparatus of claim 32, wherein the second channel signal is compensated for using a second equation,
Compensated_{—}S2=(1+x)×S2,
where S2 is a magnitude of the second channel signal, Compensated_S2 is a magnitude of the amplitude imbalance compensated second channel signal, and x is the amplitude imbalance compensation coefficient.

37. An apparatus for processing at least one complex signal, the at least one complex signal including a first channel signal and a second channel signal, the second channel signal being perpendicular to the first channel signal, the apparatus comprising:
an imbalance compensator configured to compensate for at least one of a phase imbalance and an amplitude imbalance between the first channel signal and the second channel signal based on a previously output imbalance compensated complex signal to generate an imbalance compensated complex signal, and output the imbalance compensated signal.
